(19) United States
(12) Patent Application Publication
(10) Pub. No.: US 2007/0115644 A1
(43) Pub. Date: May 24, 2007

(54) Method of cooling electronic device and electronic device with improved cooling efficiency

(75) Inventors: Sung-Hyup Kim, Suwon-si (KR); Sang-Jae Lee, Suwon-si (KR); Sun-Soo Kim, Suwon-si (KR)

Correspondence Address: STEIN, MCEWEN & BUI, LLP, 1400 EYE STREET, NW, SUITE 300, WASHINGTON, DC, 20005, US

(73) Assignee: Samsung Electronics Co., Ltd., Suwon-si (KR)

(21) Appl. No.: 11/589,740

(22) Filed: Oct. 31, 2006

(30) Foreign Application Priority Data
Nov. 22, 2005 (KR) 2005-112008

(51) Int. Cl. H05K 7/20

(52) U.S. Cl. 361/720; 165/185

(57) ABSTRACT

A method of cooling an electronic device that includes a case, a printed circuit board, and internal components. The method includes disposing a heat conductive filler having elasticity on any one of or any combination of a top surface of the printed circuit board, a bottom surface of the printed circuit board, one or more of the internal components, and an inner surface of the case during assembly of the electronic device; wherein after the electronic device has been assembled, the printed circuit, the internal components, and the heat conductive filler are disposed inside the case, and the heat conductive filler is in close contact with at least one of the internal components.

### CROSS-REFERENCE TO RELATED APPLICATION

This application claims the benefit of Korean Patent Application No. 2005-112008 filed on Nov. 22, 2005, in the Korean Intellectual Property Office, the disclosure of which is incorporated herein by reference in its entirety.

### BACKGROUND OF THE INVENTION

1. Field of the Invention

An aspect of the invention relates to a method of cooling an electronic device and an electronic device with improved cooling efficiency, and more particularly, to a method of efficiently cooling a portable compact electronic device that is difficult to cool and an electronic device that is difficult to cool with improved cooling efficiency.

2. Description of the Related Art

Portable electronic devices, such as camcorders, mobile phones, personal digital assistants (PDAs), portable multimedia players (PMPs), MP3 players, and notebook personal computers (PCs), have become smaller while being provided with more functions. Accordingly, an amount of heat generated by internal components of the electronic devices, such as a chipset, has increased. However, as electronic devices have become smaller, it has become more difficult to cool internal components of the electronic devices. There are known methods of cooling electronic devices using cooling fans, cooling fins, heat sinks, air intake vents, and the like. However, the inner space of a compact portable electronic device is so small that it is difficult to install a cooling device, such as a cooling fan, cooling fins, or a heat sink, in the small inner space. The use of such a cooling device would surely increase the overall size of the electronic device. Also, the method of naturally cooling an electronic device using an air intake vent through which ambient air enters has a limited ability to effectively cool the electronic device because the inner space of the electronic device is too small for effectively cooling.

Accordingly, various other attempts have been made to cool small portable electronic devices. For example, Korean Patent Application Publication No. 2005-61885 published on Jun. 23, 2005, discloses a method of cooling a mobile phone terminal using heat absorbing/dissipating resins.

FIG. 1 shows a lower case 10 of the mobile phone terminal. Referring to FIG. 2, in the method referred to above, heat absorbing/dissipating resins 11a and 11b are injection-molded to conform to the shape of various components mounted on a printed circuit board (PCB) of the mobile phone terminal. These heat absorbing/dissipating resins 11a and 11b are attached to the lower case 10 shown in FIG. 1. Next, the PCB is fixedly attached to the heat absorbing/dissipating resins 11a and 11b. In this method, the surfaces of the heat absorbing/dissipating resins 11a and 11b must be molded to conform to the shape of the various components mounted on the PCB. Also, the heat absorbing/dissipating resins 11a and 11b must be formed to conform to a plurality of sections defined in the lower case 10 of the mobile phone terminal.

As a result, if the design of the circuit or the case 10 is even slightly changed, the heat absorbing/dissipating resins 11a and 11b must be molded again. Accordingly, different heat absorbing/dissipating resins 11a and 11b must be used for different products or different models, thereby increasing manufacturing costs and assembly time. Furthermore, even if the surfaces of the heat absorbing/dissipating resins 11a and 11b are very precisely molded, the various components mounted on the PCB may not perfectly contact the surfaces of the heat absorbing/dissipating resins 11a and 11b due to manufacturing tolerances, thereby deteriorating cooling efficiency. Furthermore, when numerous small components are mounted on the PCB, it is difficult to precisely mold the surfaces of the heat absorbing/dissipating resins 11a and 11b to conform to the shape of the small components, thereby making the assembly process complex.

### SUMMARY OF THE INVENTION

An aspect of the invention is a method of cooling an electronic device in a simple and efficient manner without the need to use different cooling members for different products or different models.

Another aspect of invention is an electronic device with improved cooling efficiency, which can be simply manufactured and assembled.

According to an aspect of the invention, there is provided a method of cooling an electronic device, the electronic device including a case, a printed circuit board, and internal components, the method including disposing, during assembly of the electronic device, a heat conductive filler having elasticity on any one of or any combination of a top surface of the printed circuit board, a bottom surface of the printed circuit board, one or more of the internal components, and an inner surface of the case; wherein after the electronic device has been assembled, the printed circuit board, the internal components, and the heat conductive filler are disposed inside the case, and the heat conductive filler is in close contact with at least one of the internal components.

According to an aspect of the invention, after the electronic device has been assembled, the heat conductive filler may be disposed in a space between the top surface of the printed circuit board and the case; and a thickness of the heat conductive filler when the heat conductive filler is not compressed may be greater than a thickness of the space between the top surface of the printed circuit board and the case.

According to an aspect of the invention, after the electronic device has been assembled, the heat conductive filler may be disposed in a space between the bottom surface of the printed circuit board and the case; and a thickness of the heat conductive filler when the heat conductive filler is not compressed may be greater than a thickness of the space between the bottom surface of the printed circuit board and the case.

According to an aspect of the invention, the internal components may include at least one heat-generating component; and after the electronic device has been assembled, the heat conductive filler may be disposed in at least a portion of the electronic device so that the heat conductive filler is in close contact with at least one of the at least one heat-generating component.

According to an aspect of the invention, a thermal conductivity of the heat conductive filler may be at least three times higher than a thermal conductivity of air.

According to an aspect of the invention, the thermal conductivity of the heat conductive filler may be at least 0.08 W/m-K.

According to an aspect of the invention, the heat conductive filler may be made of silicone rubber or foam resin.

According to an aspect of the invention, the heat conductive filler may have a substantially flat shape when the heat conductive filler is not compressed.

According to an aspect of the invention, an electronic device includes a case; a printed circuit board disposed inside the case; internal components disposed inside the case; and a heat conductive filler having elasticity disposed on any one of or any combination of a top surface of the printed circuit board, a bottom surface of the printed circuit board, one or more of the internal components, and an inner surface of the case; wherein the heat conductive filler is in close contact with at least one of the internal components.

According to an aspect of the invention, an electronic device includes a heat-generating component; and a heat conductive filler that contacts the heat-generating component so that the heat conductive filler cools the electronic device during operation of the electronic device; wherein the heat conductive filler conforms to a shape of the heat-generating component while the heat conductive filler is disposed in the electronic device, and changes to a shape that does not conform to the shape of the heat-generating component after the heat conductive filler is removed from the electronic device.

Additional aspects and/or advantages of the invention will be set forth in part in the description which follows and, in part, will be obvious from the description, or may be learned by practice of the invention.

### BRIEF DESCRIPTION OF THE DRAWINGS

The above and/or other aspects and advantages of the invention will become apparent and more readily appreciated from the following description of the embodiments, taken in conjunction with the accompanying drawings of which:

FIG. 1 is a plan view of a lower case of an electronic device to which heat absorbing/dissipating resins of the related art are to be attached;

FIG. 2 is a plan view of the heat absorbing/dissipating resins of the related art attached to the lower case of the electronic device shown in FIG. 1;

FIG. 3 is a perspective view of an electronic device to which an aspect of the invention is to be applied;

FIG. 4 is a perspective view showing the distribution of heat generated during the operation of the electronic device shown in FIG. 3;

FIGS. 5A through 5C are cross-sectional views showing heat conductive fillers inserted into the electronic device shown in FIG. 3 according to aspects of the invention;

FIG. 6 is an exploded perspective view showing heat conductive fillers inserted into the electronic device shown in FIG. 3 according to an aspect of the invention; and

FIGS. 7 and 8 are graphs for comparing the cooling effect achieved according to an aspect of the invention with the cooling effect achieved by other methods.

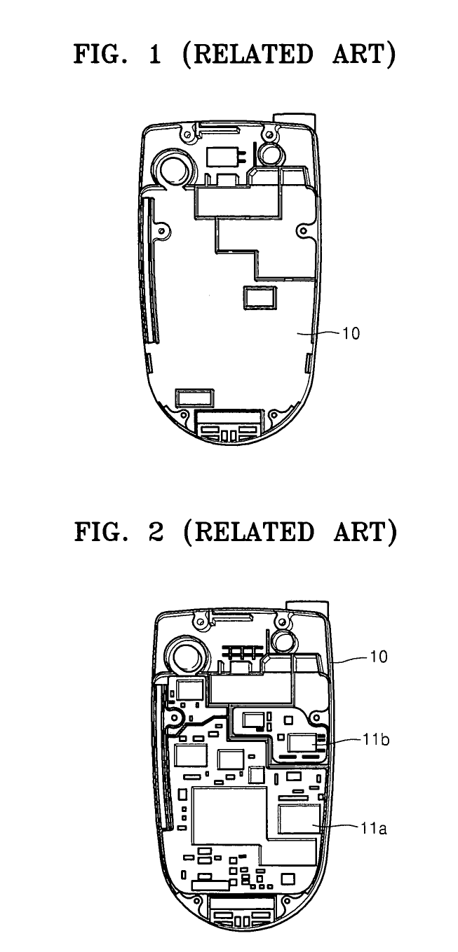

### DETAILED DESCRIPTION OF THE EMBODIMENTS

Reference will now be made in detail to embodiments of the invention, examples of which are shown in the accompanying drawings, wherein like reference numerals refer to like elements throughout. The embodiments are described below in order to explain the invention by referring to the figures.

Conventional methods have limitations in terms of dissipating heat generated by internal components of small portable electronic devices. To effectively cool internal components of an electronic device, a method according to an aspect of the invention inserts a heat conductive filler made of a material having elasticity and heat resistance, such as foam resin such as a sponge, or silicone rubber, into an empty space in the electronic device so that the heat conductive filler is in close contact with the internal components of the electronic device. Here, close contact refers to a state in which there is no space or substantially no space between a surface of the heat conductive filler and a surface of any internal component of the electronic device opposing the heat conductive filler. The cooling effect achieved by the heat conductive filler can be determined using temperature distribution data provided by a thermal flow analysis performed under various conditions.

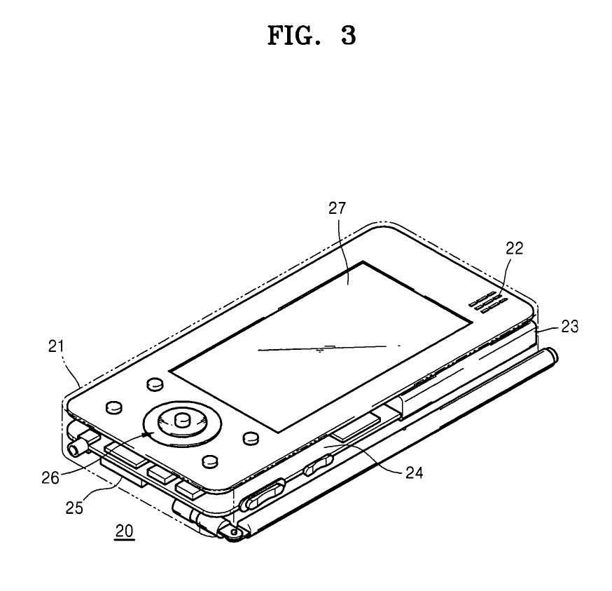

FIG. 3 is a perspective view of a portable multimedia player (PMP) 20 marketed under the brand name YM-P1 by the assignee of this application to which an aspect of the invention is to be applied. Referring to FIG. 3, the PMP 20 is configured in such a manner that a display panel 27, such as a liquid crystal display (LCD), a keypad 26, and a small speaker 22 are disposed on a top surface of a case 21. A printed circuit board (PCB) 24 on which various electronic components are mounted is fixedly installed in the case 21. A battery 23 is mounted on a side of the PCB 24, and a hard disk drive (HDD) 25 is disposed under the PCB 24.

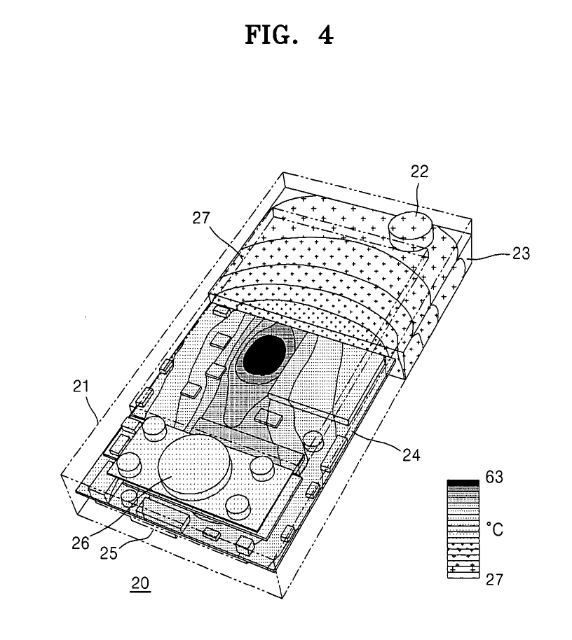

FIG. 4 is a perspective view showing the distribution of heat generated during the operation of the PMP 20 shown in FIG. 3 obtained by performing a thermal flow analysis in which temperature measurements at various locations in the PMP 20 are simulated. Referring to FIG. 4, when there is no cooling device in the PMP 20, the highest temperature at the center of the PCB 24 exceeds approximately 60° C.

An aspect of the invention employs a heat conductive filler having elasticity and heat resistance as a device for cooling heat-generating electronic components mounted on the PCB 24.

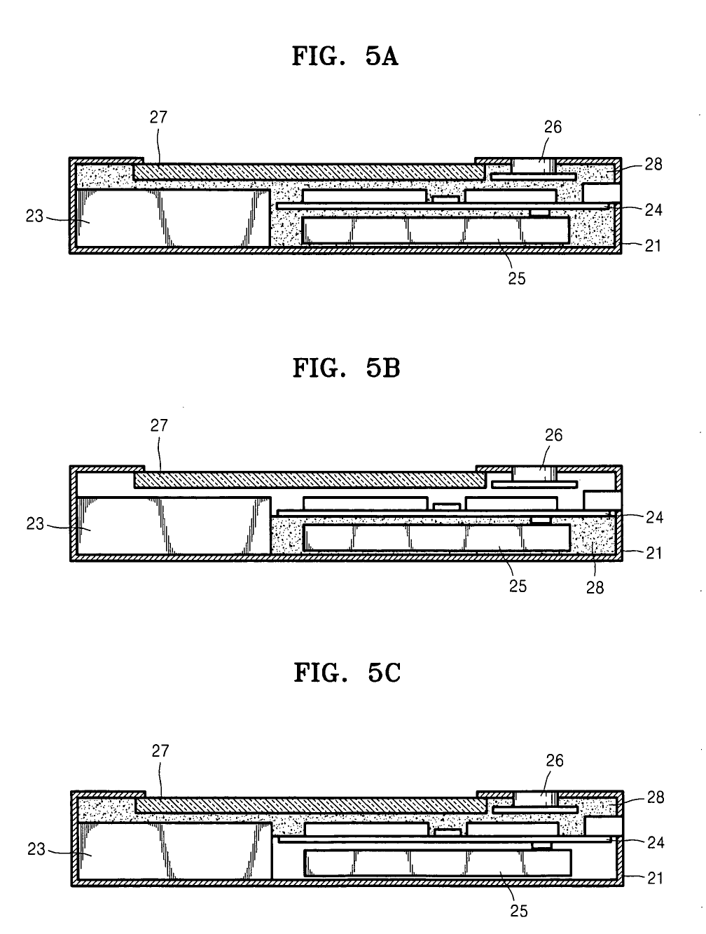

FIGS. 5A through 5C are cross-sectional views showing heat conductive fillers inserted into the PMP 20 shown in FIG. 3 according to aspects of the invention. A heat conductive filler 28 may be inserted into substantially the entire empty space in the PMP 20 as shown in FIG. 5A. When the heat-generating components are mounted only on a bottom surface of the PCB 24, the heat conductive filler 28 may be inserted only under the PCB 24 as shown in FIG. 5B. When the heat-generating components are mounted only on a top surface of the PCB 24, the heat conductive filler 28 may be inserted only above the PCB 24 as shown in FIG. 5C.

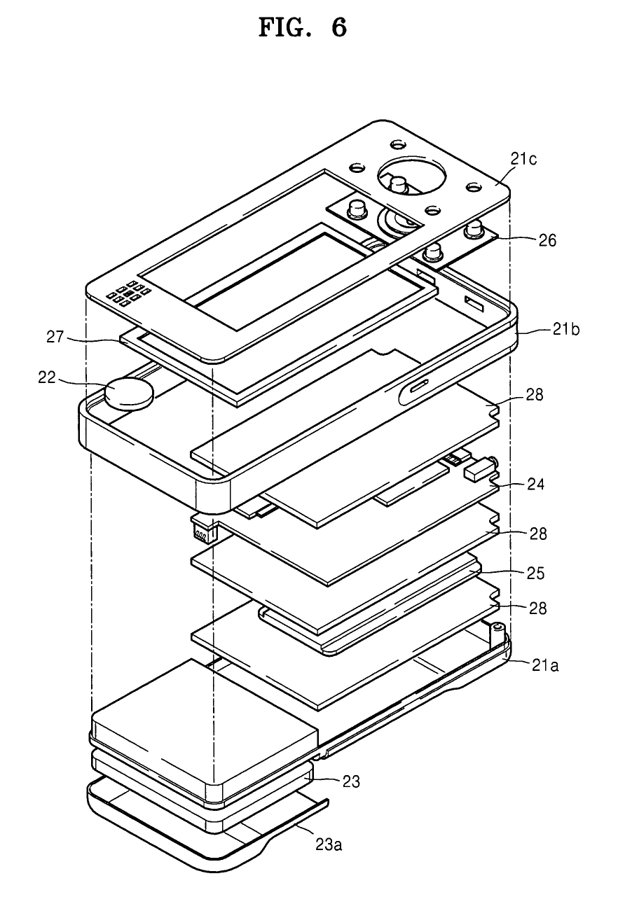

FIG. 6 is an exploded perspective view showing heat conductive fillers inserted into the PMP 20 shown in FIG. 3 according to an aspect of the invention. Referring to FIG. 6, substantially flat heat conductive fillers 28 having elasticity and heat resistance are inserted into substantially the entire empty space in the PMP 20. That is, the heat conductive fillers 28 having elasticity and heat resistance are disposed between the top surface of the PCB 24 and the display panel 27, between the bottom surface of the PCB 24 and the HDD 25, and between a lowercase 21a and the HDD 25. In this case, the thickness of each of the heat conductive fillers 28 when it is not compressed may be greater than the thickness of the space in which the heat conductive filler 28 is disposed after the assembly of the PMP 20. After the heat conductive fillers 28 have been disposed in this manner, the lower case 21a, a side case 21b, and an upper case 21c are fixedly assembled together so that the heat conductive fillers 28 are compressed to be in close contact with the internal components of the PMP 20. For example, since the heat conductive filler 28 disposed between the top surface of the PCB 24 and the display panel 27 is compressed against the PCB 24 by the display panel 27 after the assembly of the PMP 20, the heat conductive filler 28 can be in close contact with electronic components mounted on the top surface of the PCB 24. In particular, since the heat conductive filler 28 has elasticity, the heat conductive filler 28 can uniformly contact all the electronic components mounted on the top surface of the PCB 24 irrespective of their height and size. Alternatively, the heat conductive filler 28 may be directly attached to an inner surface of the upper case 21c and/or the lower case 21a before the assembly of the PMP 20. The reference numeral 23a in FIG. 6 denotes a battery case.

Although FIGS. 5A through 5C and FIG. 6 show the YM-P1 PMP 20 as the electronic device, the heat conductive filler 28 can be applied to other electronic devices, such as camcorders, mobile phones, personal digital assistants (PDAs), MP3 players, and notebook personal computers (PCs). Although the heat conductive filler 28 is in close contact with the entire area of the PCB 24 in FIGS. 5A through 5C and FIG. 6, the heat conductive filler 28 may be disposed to be in close contact with only a part of the entire area of the PCB 24 so as to be in close contact with only heat-generating components among the electronic components mounted on the PCB 24.

The heat conductive filler 28 may be made of a material having elasticity and heat resistance, and the thermal conductivity of the heat conductive filler 28 may be at least three times higher than that of air. In general, since the thermal conductivity of air is approximately 0.026 W/m-K at 1 atm and 27° C., the thermal conductivity of the heat conductive filler 28 may be at least approximately 0.08 W/m-K to ensure a cooling effect. Accordingly, the material of the heat conductive filler 28 may be foam resin such as a sponge, or more preferably, may be silicone rubber. Both the sponge and the silicone rubber have high elasticity and high heat resistance. Here, elasticity refers to an ability of the heat conductive filler 28 to be compressed by a force applied by a human and to return to an original shape after the force is removed. Such an elasticity enables the heat conductive filler 28 to conform to shapes of components of the PMP 20 without damaging those components when the heat conductive filler 28 is compressed against those components during assembly of the PMP 20. Also, heat resistance refers to an ability of the heat conductive filler 28 to withstand heat generated in the heat-generating electronic components during operation of the PMP 20, not an ability to withstand high temperature heat of many hundreds of degrees Celsius. For example, the heat resistance of the sponge may be about 100° C., and the heat resistance of the silicone rubber may be about 200° C. Also, since the thermal conductivity of the sponge is approximately 0.4 W/m-K and the thermal conductivity of the silicone rubber is approximately 2 W/m-K, both the sponge and the silicone rubber can satisfy the thermal conductivity conditions for the heat conductive filler 28.

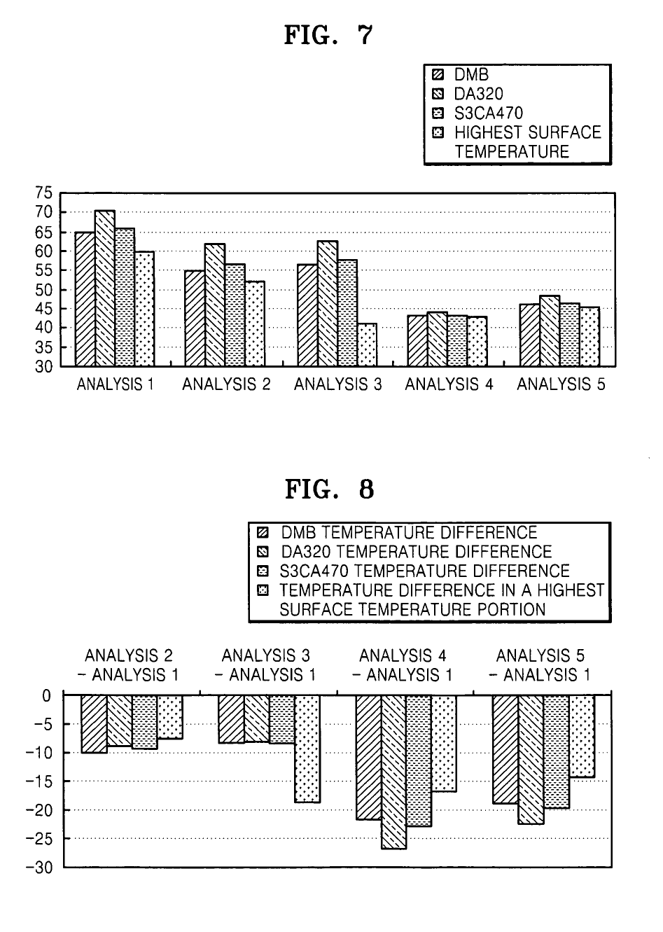

FIGS. 7 and 8 are graphs for comparing the cooling effect achieved according to an aspect of the invention and the cooling effect achieved by other methods. FIGS. 7 and 8 show results obtained after a thermal flow analysis was performed. The thermal flow analysis was performed on the PMP 20 shown in FIG. 3 using a 3D finite volume model under conditions of 1 atm and 27° C. outside of the PMP 20. It was assumed that heat sources existing on the PCB 24 of the PMP 20 include only a digital multimedia broadcasting (DMB) chip, a DA320 chip, and an S3CA470 chip, which are standard chips used for DMB. There was a difference of approximately 8.8° C. between results obtained from the thermal flow analysis performed using the model and results obtained by taking actual temperature measurements at various locations in the PMP 20. The graphs of FIGS. 7 and 8 were obtained after correcting for this difference.

Referring to FIGS. 7 and 8, analysis 1 is a case where no heat conductive filler 28 is inserted into the PMP 20 shown in FIG. 3. Analysis 2 is a case where no heat conductive filler is inserted into the PMP 20 and the upper case 21c is removed so that the inner heat sources can be in direct contact with ambient air. Analysis 3 is a case where no heat conductive filler is inserted into the PMP 20 and the material of the case 21 is aluminum instead of plastic. Analysis 4 is a case where a heat conductive filler made of silicone rubber is inserted into the PMP 20. Analysis 5 is a case where a heat conductive filler made of a sponge is inserted into the PMP 20.

Referring to FIG. 7, in the case of analysis 1, the temperatures of the heat sources, that is, the DMB chip, the DA320 chip, and the S3CA470 chip, in the PMP 20 reached approximately 65 to 70° C., and the surface temperature of the case 21 was approximately 60° C. In the case of analysis 2, the temperatures of the heat sources were approximately 55 to 62° C. and the surface temperature of the case 21 was approximately 52° C., which is considered to be the lowest temperature obtainable by natural convection. In the case of analysis 3, the temperatures of the heat sources were similar to those of the heat sources in the case of analysis 2, but the surface temperature of the case 21 was approximately 41° C. In the case of analysis 4, both the temperatures of the heat sources and the surface temperature of the case 21 were approximately 43 to 44° C. In the case of analysis 5, both the temperatures of the heat sources and the surface temperature of the case 21 were approximately 45 to 49° C. When analysis 4 and analysis 5 are compared, although there is a great difference in thermal conductivity between the silicone rubber and the sponge, both analysis 4 and analysis 5 showed similar cooling effects.

FIG. 8 is a graph showing how much the temperatures of the heat sources and the surface temperature of the case 21 in the analyses 2 through 5 changed from those in analysis 1. Referring to FIG. 8, analysis 2 showed that the temperatures of the heat sources and the surface temperature of the case 21 dropped by approximately 10° C. Analysis 3 showed that the temperatures of the heat sources dropped by approximately 10° C. and the surface temperature of the case 21 dropped by approximately 20° C. Analysis 4 showed that the temperatures of the heat sources dropped by approximately 22 to 26° C. and the surface temperature of the case 21 dropped by approximately 16° C. Analysis 5 showed that the temperatures of the heat sources dropped by approximately 18 to 22° C. and the surface temperature of the case 21 dropped by approximately 14° C.

Accordingly, when the heat conductive filler made of a sponge or silicone rubber is inserted into the empty space in the electronic device as shown in FIGS. 5A through 5C and FIG. 6, the electronic device can be simply cooled without increasing its size.

As described above, since the heat conductive filler made of a sponge or silicone rubber is inserted into the empty space of the electronic device, the electronic device can be simply and efficiently cooled without increasing its size. Furthermore, since the process of disposing the heat conductive filler having elasticity on the heat sources is simply added to the assembly of the electronic device, the assembly process is not complex. Moreover, since the surface of the heat conductive filler does not have to be molded to have a specific shape, different heat conductive fillers do not need to be used for different products or different models, thereby simplifying the manufacturing process and reducing manufacturing costs.

Although several embodiments of the invention have been shown and described, it would be appreciated by those skilled in the art that changes may be made in these embodiments without departing from the principles and spirit of the invention, the scope of which is defined in the claims and their equivalents.

What is claimed is:

1. A method of cooling an electronic device, the electronic device comprising a case, a printed circuit board, and internal components, the method comprising:
disposing, during assembly of the electronic device, a heat conductive filler having elasticity on any one of or any combination of
a top surface of the printed circuit board,
a bottom surface of the printed circuit board,
one or more of the internal components, and
an inner surface of the case;
wherein after the electronic device has been assembled, the printed circuit board, the internal components, and the heat conductive filler are disposed inside the case, and the heat conductive filler is in close contact with at least one of the internal components.

2. The method of claim 1, wherein after the electronic device has been assembled, the heat conductive filler is disposed in a space between the top surface of the printed circuit board and the case; and
wherein a thickness of the heat conductive filler when the heat conductive filler is not compressed is greater than a thickness of the space between the top surface of the printed circuit board and the case.

3. The method of claim 1, wherein after the electronic device has been assembled, the heat conductive filler is disposed in a space between the bottom surface of the printed circuit board and the case; and
wherein a thickness of the heat conductive filler when the heat conductive filler is not compressed is greater than a thickness of the space between the bottom surface of the printed circuit board and the case.

4. The method of claim 1, wherein the internal components comprise at least one heat-generating component; and
wherein after the electronic device has been assembled, the heat conductive filler is disposed in at least a portion of the electronic device so that the heat conductive filler is in close contact with at least one of the at least one heat-generating component.

5. The method of claim 1, wherein a thermal conductivity of the heat conductive filler is at least three times higher than a thermal conductivity of air.

6. The method of claim 5, wherein the thermal conductivity of the heat conductive filler is at least 0.08 W/m-K.

7. The method claim 1, wherein the heat conductive filler is made of silicone rubber or foam resin.

8. The method of claim 1, wherein the heat conductive filler has a substantially flat shape when the heat conductive filler is not compressed.

9. The method of claim 1, wherein at least one of the internal components is mounted on the printed circuit board.

10. The method of claim 1, wherein the internal components comprise at least one heat-generating component; and
wherein the heat conductive filler has a heat resistance that is sufficient to resist heat generated by the at least one heat-generating component during operation of the electronic device.

11. An electronic device comprising:
a case;
a printed circuit board disposed inside the case;
internal components disposed inside the case; and
a heat conductive filler having elasticity disposed on any one of or any combination of
a top surface of the printed circuit board,
a bottom surface of the printed circuit board,
one or more of the internal components, and
an inner surface of the case;
wherein the heat conductive filler is in close contact with at least one of the internal components.

12. The electronic device of claim 11, wherein the heat conductive filler is disposed in a space between the top surface of the printed circuit board and the case; and
wherein a thickness of the heat conductive filler when the heat conductive filler is not compressed is greater than a thickness of the space between the top surface of the printed circuit board and the case.

13. The electronic device of claim 11, wherein the heat conductive filler is disposed in a space between the bottom surface of the printed circuit board and the case; and
wherein a thickness of the heat conductive filler when the heat conductive filler is not compressed is greater than a thickness of the space between the bottom surface of the printed circuit board and the case.

14. The electronic device of claim 11, wherein the internal components comprise at least one heat-generating component; and
wherein the heat conductive filler is disposed in at least a portion of the electronic device so that the heat conductive filler is in close contact with at least one of the at least one heat-generating component.

15. The electronic device of claim 11, wherein a thermal conductivity of the heat conductive filler is at least three times higher than a thermal conductivity of air.

16. The electronic device of claim 15, wherein the thermal conductivity of the heat conductive filler is at least 0.08 W/m-K.

17. The electronic device of claim 11, wherein the heat conductive filler is made of silicone rubber or foam resin.

18. The electronic device of claim 11, wherein the heat conductive filler has a substantially flat shape when the heat conductive filler is not compressed.

19. The electronic device of claim 11, wherein at least one of the internal components is mounted on the printed circuit board.

20. The electronic device of claim 11, wherein the internal components comprise at least one heat-generating component; and
wherein the heat conductive filler has a heat resistance that is sufficient to resist heat generated by the at least one heat-generating component during operation of the electronic device.

21. An electronic device comprising:
a heat-generating component; and
a heat conductive filler that contacts the heat-generating component so that the heat conductive filler cools the electronic device during operation of the electronic device;
wherein the heat conductive filler conforms to a shape of the heat-generating component while the heat conductive filler is disposed in the electronic device, and changes to a shape that does not conform to the shape of the heat-generating component after the heat conductive filler is removed from the electronic device.

22. The electronic device of claim 21, wherein the heat conductive filler is in close contact with the heat-generating component.

23. The electronic device of claim 21, wherein the heat conductive filler has elasticity.

24. The electronic device of claim 23, wherein the heat conductive filler has a heat resistance that is sufficient to resist heat generated by the heat-generating component during the operation of the electronic device.

25. The electronic device of claim 21, wherein the heat conductive filler has a thermal conductivity that enables the heat conductive filler to cool the electronic device to a desired temperature during the operation of the electronic device.

26. The electronic device of claim 25, wherein the thermal conductivity of the heat conductive filler is at least three times higher than a thermal conductivity of air.

27. The electronic device of claim 26, wherein the thermal conductivity of the heat conductive filler is at least 0.08 W/m-K.

28. The electronic device of claim 21, wherein the heat conductive filler is made of foam resin or silicone rubber.

29. The electronic device of claim 21, wherein the heat conductive filler changes to a substantially flat shape after the heat conductive filler is removed from the electronic device.

30. The electronic device of claim 21, wherein a thickness of the heat conductive filler after the heat conductive filler is removed from the electronic device is greater than a thickness of the heat conductive filler while the heat conductive filler is disposed in the electronic device.

31. The electronic device of claim 21, further comprising:
a case; and
a printed circuit board;
wherein the printed circuit board and the heat-generating component are disposed inside the case; and
wherein the heat-generating component is mounted on the printed circuit board.

32. The electronic device of claim 31, wherein the heat conductive filler occupies substantially an entire space inside the case that is not occupied by any other element of the electronic device.

33. The electronic device of claim 31, wherein the printed circuit board comprises a first surface facing a first portion of an inner surface of the case, and a second surface facing a second portion of the inner surface of the case; the first surface and the second surface being on opposite sides of the printed circuit board; and
wherein the heat conductive filler is disposed between at least a portion of the first surface of the printed circuit board and at least a portion of the first portion of the inner surface of the case, and/or between at least a portion of the second surface of the printed circuit board and at least a portion of the second portion of the inner surface of the case.
